(19) United States
(12) Patent Application Publication
(10) Pub. No.: US 2005/0099187 A1
(43) Pub. Date: May 12, 2005

(54) Method of diagnosing a fault on a transformer winding

(75) Inventor: Simon Andrew Ryder, Oxford (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: AREVA T&D SA, Paris-La-Defense (FR)

(21) Appl. No.: 10/954,231

(22) Filed: Oct. 1, 2004

(30) Foreign Application Priority Data
Oct. 3, 2003 (FR) 03 11640

(51) Int. Cl. H02M 3/335; G01R 31/06

(52) U.S. Cl. 324/547

(57) ABSTRACT

This invention relates to a method of diagnosing one fault on a transformer winding using a Frequency Response Analysis (FRA). This invention is adapted more particularly to power transformers. The method comprises the following steps: measure the impedance of the said winding as a function of the frequency, the said measurement being represented in the form of a first voltage gain k, compare the said impedance measurement with a reference measurement represented in the form of a second voltage gain k′. The method also comprises a step to determine the relative variation of the first resonant frequency exceeding 10 kHz, the said relative variation being obtained by comparing the said first and second gains k and k′.

This invention relates to a method of diagnosing a fault on a transformer winding using a Frequency Response Analysis (FRA). This invention is adapted more particularly to power transformers.

Power transformers (such as transformers with primary voltages of several hundred kV and output powers varying from a few MVA to several hundred MVA) are extremely expensive devices in transmission network interconnection systems. Therefore it is very useful to be able to keep these transformers in service for as long as possible, since a failure or a fault in the transformer can have serious economic consequences because the distribution network is shut down.

Furthermore, faults such as short circuits can cause risks of explosion or fire.

Therefore, it is very important to be able to determine the presence of a fault related to a transformer winding.

One known solution to this problem consists of using a Frequency Response Analysis (FRA). This technique consists of measuring the impedance of a transformer winding over a wide frequency range and comparing the result of these measurements with a reference set. The impedance can be measured as a function of the frequency by doing a frequency scan using a sinusoidal signal.

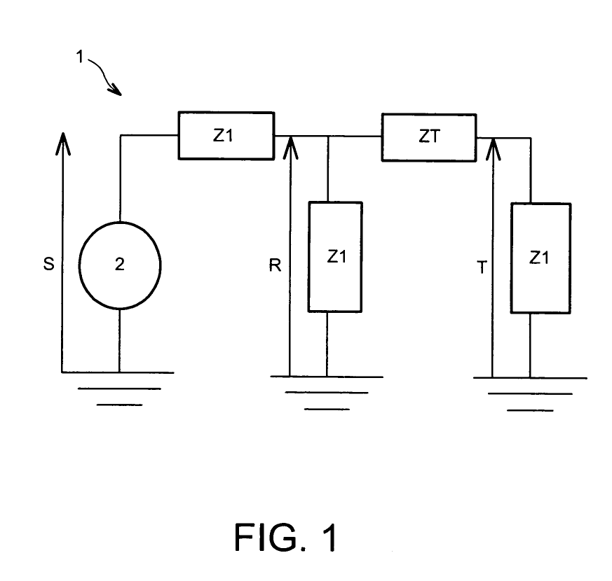

Thus, FIG. 1 shows a principle diagram for a frequency analysis circuit 1 for an impedance corresponding to the impedance of a transformer winding to be measured.

The circuit 1 comprises:
a network analyser 2,
three test impedances with the same value Z1,
an impedance ZT corresponding to the impedance of a transformer winding to be measured.

The network analyser 2 generates a measurement signal S. The measurement signal S is a frequency scanned sinusoidal signal. Impedances Z1 may for example be impedances of measurement cables and their value is usually 50 Ohms. R is the signal measured between the first end of ZT and the ground. T is the signal measured between the second end of ZT and the ground. The analyser 2 then represents the voltage gain k as a function of the frequency, defined by the following relation:

$$k = 20 {log}_{10} ( \frac{T}{R} )$$

The gain k contains information necessary for studying the impedance ZT and is equal to:

$$k = 20 {log}_{10} ( \frac{Z1}{Z1 + ZT} ) .$$

The result for an impedance Z1 equal to 50 Ohms is:

$$k = 20 {log}_{10} ( \frac{50}{50 + ZT} ) .$$

The impedance is measured over a very wide frequency range that may vary from a few Hz to a few tens of MHz.

The same measurement must be made on a reference winding. This reference winding may be either another phase for which it is assumed that there is no fault, or the same winding measured before there was a fault, or a winding of an identical transformer. Therefore, a gain k′ is obtained as a function of the frequency corresponding to this reference winding.

A first solution then consists of examining differences between the curves representing k and k′ as a function of the frequency, by eye.

However, this solution does create problems.

Firstly an examination by eye introduces subjectivity and a lack of transparency.

A second solution consists of calculating statistical indicators to demonstrate differences between the two curves. For example, this type of statistical indicator may include correlation coefficients calculated in different frequency ranges.

However, the use of these statistical indicators also introduces some problems.

Thus, some faults cannot be identified; for example, this is the case of earthing of the transformer magnetic circuit or a circulation current that overheats the transformer.

Similarly, this use of statistical indicators can cause confusion between some faults; for example, poor earthing of the transformer tank may be confused with winding damage.

A third solution is described in the document entitled “a new method for diagnosing transformer faults using Frequency Response Analysis” (Simon Ryder, proceedings of the CIGRE committee A2 conference, Merida, Mexico, Jun. 1-3 2003, pages 123-135). With this method, three correlation factors ρ₁, ρ₂ and ρ₃ are calculated for k and k′ on the three frequency ranges [1 kHz-10 kHz], [10 kHz-100 kHz] and [100 kHz-1 MHz], together with the relative variations of the minimum gain determined for a frequency below 10 kHz, the fundamental resonant frequency and the number of resonant frequencies present in a predetermined interval. This method has the advantage that it enables an increase in the number of detectable faults and better distinction between different faults.

However, there are other difficulties with implementation of this third solution; thus, in particular, this method cannot make a distinction between a fault related to an axial displacement of the winding to be analysed when there is no local damage to the winding, and a fault related to buckling of an inner winding.

This invention is intended to provide a method of diagnosing at least one fault on a transformer winding, and to make a better distinction between different faults.

To achieve this, this invention proposes a method of diagnosing at least one fault on a transformer winding comprising the following steps:
measure the impedance of the said winding as a function of the frequency, the said measurement being represented in the form of a first voltage gain,
compare the said impedance measurement with a reference measurement represented in the form of a second voltage gain, the said method being characterised in that it comprises a step to determine the relative variation of the first resonant frequency exceeding 10 kHz, the said relative variation being obtained by comparing the said first and second gains.

According to the invention, determination of the relative variation of the first resonant frequency more than 10 kHz provides a means of making a distinction between a fault related to an axial displacement of the winding to be analysed without any local damage, and a fault related to buckling of an inner winding. Note that in general, the relative variation of a resonant frequency is determined as follows:

$${VR}_{f} = \frac{f}{{f}^{′}}$$

where f denotes the first resonant frequency associated with the first gain and f′ denotes the first resonant frequency associated with the second gain.

Advantageously, the method includes a step to determine the relative variation of the last resonant frequency less than 1 MHz.

Advantageously, the method includes a step to determine the presence of a resonant frequency less than the fundamental resonant frequency.

Advantageously, the method includes a step to determine the absolute variation of the maximum gain within a predetermined interval.

The maximum gain is defined as being the maximum value taken by the voltage gain k as described with reference to FIG. 1 as a function of the measurement frequency, for example, the maximum gain to be determined is the maximum gain for a frequency that may be more than 1 kHz. It is possible that the gain will be maximum for a frequency of less than 1 kHz, but this value is not very relevant for fault identification. An upper limit can also be fixed for the maximum gain calculation, for example 100 kHz. Note also that the objective in this case is to calculate the absolute (not relative) variation of the maximum gain, which can be defined as follows:
VAₖ=max(k)−max(k′)

With this embodiment, the said predetermined interval is advantageously [1 kHz; 100 kHz].

Advantageously, the method includes a step to determine the relative variation of a second resonant frequency following the fundamental resonant frequency.

According to one particularly advantageous embodiment, the method includes the following steps:
determine four correlation coefficients of the said first and second gains in the four frequency ranges [100 Hz, 1 kHz], [1 kHz-10 kHz], [10 kHz-100 kHz] and [100 kHz-1 MHz],
determine the relative variation of the minimum gain for a frequency less than 10 kHz,
determine the absolute variation of the maximum gain in a predetermined frequency interval,
determine the relative variation of the fundamental resonant frequency,
determine if a second resonant frequency is present following the fundamental resonant frequency,
determine the relative variation of the said second resonant frequency following the fundamental resonant frequency,
determine if a resonant frequency is present less than the fundamental resonant frequency,
determine the relative variation of the last resonant frequency less than 1 MHz,
determine the relative variation of the number of resonant frequencies within a predetermined interval.

Advantageously, the said relative variation of the number of resonant frequencies is made within the interval [100 kHz; 1 MHz].

Advantageously, the said determination of the absolute variation of the maximum gain is made within the interval [1 kHz; 100 kHz].

According to one particularly advantageous embodiment, the method includes the following steps:
inject the results of each of the said determinations of relative variation and/or presence into an expert computer system,
the said expert system determines and identifies fault(s).

An expert system is a computer program that simulates the behaviour of a human expert. The expert system does this using rules for the interpretation of data. The advantages of an expert system lie in the fact that the expertise is represented in a manner that is very easily understandable by the programmer; furthermore, an expert system has a uniform structure based on rules that are essentially self-documented. Furthermore, the expertise is completely separate from data processing. Finally, an expert system processes uncertainties by making a decision based on a particular rule and also provides a means of processing a large amount of information that a human expert could not process quickly.

According to this embodiment, the method advantageously includes the following steps:
assignment of a certainty factor to each fault that might be determined,
determination and identification of the fault(s) based on several rules modifying the said certainty factors as a function of the said results of each of the said determinations of relative variation and/or presence.

Advantageously, the method of calculating each certainty factor is based on the following principles:
If CF′>0 and CF″>0 then
   CF=CF′+CF″(1−CF′)
If CF′=0
   CF=CF″
If CF′>0 and CF″<0 or if CF′<0 and CF″>0
then:

$$CF = \frac{{CF}^{′} + {CF}^{″}}{1 - min ( \vert {CF}^{′} \vert , \vert {CF}^{″} \vert )}$$
If CF′<0 and CF″<0 then
   CF=CF′+CF″(1+CF′)
   where CF denotes the current value of the certainty factor, CF′ denotes the value before application of one of the said rules, and CF″ denotes the value of the certainty factor determined from one of the said rules and applied to CF′.

Another purpose of this invention is an expert computer system for implementation of the method according to the invention characterised in that it comprises:
a plurality of inputs adapted to receive the results of each of the said determinations of relative variation and/or presence indicators,
a plurality of outputs called intermediate outputs, corresponding to the number of detectable faults, each output being adapted to output a certainty factor calculated from the said plurality of rules,
a so-called final output adapted to produce a diagnostic of the fault(s) present on the said transformer winding.

Other characteristics and advantages of this invention will become clearer after reading the following description of an embodiment of the invention given for illustrative purposes, and in no way limitative.

In the following figures:

FIG. 1 diagrammatically shows an impedance Frequency Response Analysis circuit,

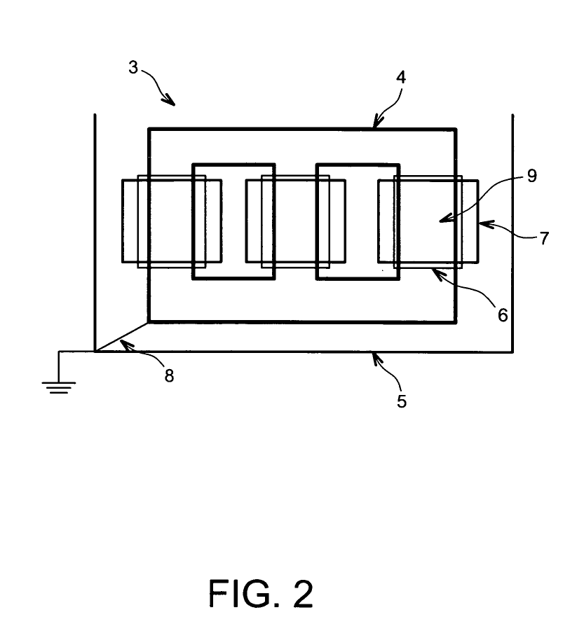

FIG. 2 diagrammatically shows a three-phase transformer,

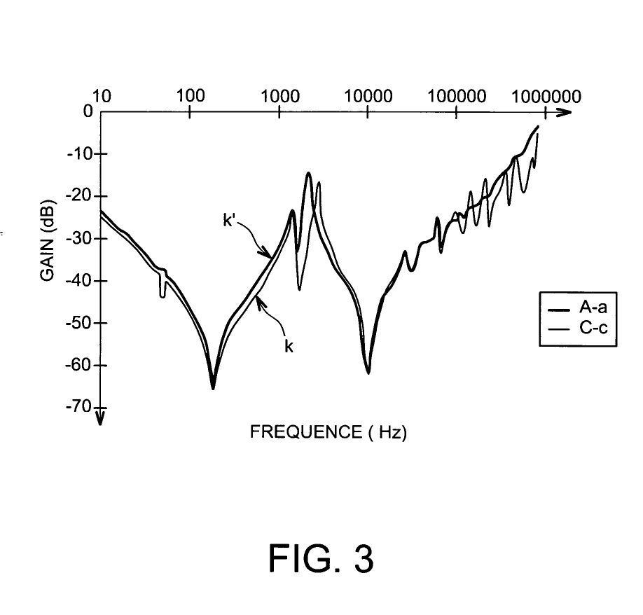

FIG. 3 shows the corresponding gains as a function of the frequency of two high voltage windings of two phases of a three-phase transformer.

FIG. 1 has already been described relative to the state of the art. The FRA measurements presented in the following will always be made using an analysis circuit like that shown in FIG. 1.

FIG. 2 diagrammatically shows a three-phase transformer 3.

The three-phase transformer 3 comprises:
a magnetic circuit 4,
a tank 5,
three low voltage windings 6,
three high voltage windings 7.

Each pair of high and low voltage windings corresponds to one transformer phase associated with a core 9 in the circuit 4. The three transformer phases will be noted A, B and C in the remainder.

The magnetic circuit 4 and the tank 5 are connected by a connection 8 and are grounded.

Three impedance measurements may be made for each of the high and low voltages.

Thus, if a fault is suspected on one of the high voltage windings of the transformer, the gain of this winding is measured as a function of the frequency, the same measurement is made for another high frequency winding and the corresponding gains of these two windings are compared. Note that a third measurement can also be made using the third high frequency winding.

Note that a comparison can also be made between the measurements on the suspected winding and measurements previously made on the same winding. A comparison can also be made between the measurements on the suspected winding and an equivalent winding of another transformer with the same design.

For example FIG. 3 shows the gains k and k′ of the high voltage windings of phases C and A respectively of a three-phase transformer like that shown in FIG. 2.

The gains k and k′ are shown for a frequency varying from 10 Hz to 1 MHz.

The method according to the invention includes determination of the following eleven parameters to determine the presence of a fault and to diagnose it:

The first four parameters are correlation coefficients ρ₁, ρ₂ and ρ₃ and ρ₄ for k and k′ calculated on the three frequency ranges [100 Hz-1 kHz], [1 kHz-10 kHz], [10 kHz-100 kHz] and [100 kHz-1 MHz].

Remember that the correlation coefficient ρ for two sets of n numbers X{x₁, x₂, . . . , xₙ} and Y{y₁, y₂, . . . , yₙ} is defined by the following relation:

$$ρ = {\sum }_{x = i}^{n} {x}_{i} {y}_{i} / \sqrt{{\sum }_{i = 1}^{n} {x}_{i}^{2} {\sum }_{i = 1}^{n} {y}_{i}^{2}} .$$

The fifth parameter is defined as the relative variation VR_{f1} of the fundamental resonant frequency. The fundamental resonant frequency is the first resonant frequency of each of the gains k and k′. If the fundamental resonant frequencies of the gains k and k′ are called f1 and f1′ respectively, the parameter VR_{f1} is defined by the relation:

$${VR}_{f1} = \frac{f1}{{f1}^{′}}$$

The sixth parameter is defined as the relative variation VR_{f2} of the second resonant frequency immediately after the fundamental resonant frequency. The parameter VR_{f2} is defined by the relation:

$${VR}_{f2} = \frac{f2}{{f2}^{′}} ,$$

where f2 and f2′ denote the second resonant frequencies of k and k′ respectively.

The seventh parameter is defined as the relative variation VR_{f3} of the first resonant frequency above 10 kHz. The parameter VR_{f3} is defined by the relation

$$VRf3 = \frac{f3}{{f3}^{′}} ,$$

where f3 and f3′ denote the first resonant frequencies of k and k′ respectively above 10 kHz.

The eighth parameter is defined as being equal to the relative variation VR_{f4} of the last resonant frequency below 1 MHz. The parameter VR_{f4} is defined by the relation

$${VR}_{f4} = \frac{f4}{{f4}^{′}} ,$$

where f4 and f4′ denote the last resonant frequencies of k and k′ respectively below 1 MHz.

The ninth parameter is defined as being equal to the relative variation of the minimum gain VRₖ₁ at low frequency, in other words at a frequency value below 10 kHz. Thus, if k1 is the minimum gain of the impedance to be analysed and k1′ is the minimum gain of the reference impedance, the parameter VRₖ₁ is defined by the relation

$${VR}_{k1} = \frac{k1}{{k1}^{′}} .$$

The tenth parameter is defined as being equal to the absolute variation VAₖ₂ of the maximum gain for a frequency between 1 kHz and 100 kHz. Thus, if k2 is the maximum gain of the impedance to be analysed and k2′ is the maximum gain of the reference impedance, the parameter VAₖ₂ is defined by the relation:
VAₖ₂=k2−k2′

The eleventh parameter is defined as being equal to the relative variation VRₙ of the number of resonant frequencies between 100 kHz and 1 MHz. The parameter VRₙ is defined by the relation

$${VR}_{n} = \frac{n}{{n}^{′}} ,$$

where n and n′ denote the number of higher resonant frequencies of k and k′ respectively within the interval [100 kHz-1 MHz].

The method according to the invention also includes the determination of the presence of a blip type resonant frequency, in other words a resonant frequency less than the fundamental resonant frequency and with low amplitude. The presence of a blip type frequency introduces a logical indicator that can be equal to one of two values depending on whether or not the frequency is present.

The method according to the invention also includes the determination of the presence of a second resonant frequency following the fundamental resonant frequency. The presence of such a second resonant frequency introduces a logical indicator that can be equal to one of two values depending on whether or not the frequency is present.

All these eleven parameters accompanied by presence indicators of a blip frequency and a second resonant frequency are injected into an expert system characterised by a plurality of certainty factors Ci. The number of certainty factors corresponds to the number of faults that could be detected by the expert system. The fourteen detectable fault types and their associated certainty factors are summarised in table 1 below.

TABLE 1

| Fault type | Certainty factor |
|---|---|
| 1) Poor earthing of the | C1 |
| tank (high resistance)/no | |
| earthing of the tank | |
| 2) No earthing of the | C2 |
| magnetic circuit | |
| 3) Closed loop earthed/ | C3 |
| closed loop put at a | |
| floating potential | |
| 4) Additional turn short | C4 |
| circuited (same phase) | |
| 5) Fault between winding | C5 |
| terminals (analysed winding | |
| affected) | |
| 6) Fault between winding | C6 |
| terminals (other winding of | |
| the same phase affected) | |
| 7) One turn short circuited | C7 |
| 8) Several turns short | C8 |
| circuited | |
| 9) Short circuit on the | C9 |
| adjacent phase alone | |
| 10) Short circuit on a | C10 |
| phase other than the | |
| adjacent phase alone | |
| 11) Winding displaced | C11 |
| 12) Buckling of the inner | C12 |
| winding | |
| 13) Winding damaged | C13 |
| 14) Poor continuity | C14 |

The following explanation of the faults will be made with reference to FIG. 2.

Fault 1 corresponds to poor earthing of the tank 5; it may be caused by lack of earthing or earthing with high resistance between the tank 5 and the earth (more than 50 Ohms).

Fault 2 corresponds to a lack of earthing of the magnetic circuit 4, in other words a break in the connection 8.

Fault 3 corresponds to a circulation current loop being connected either to the earth or to a floating potential, these loops causing overheating of the transformer.

Fault 4 corresponds to the presence of an additional turn creating a short circuit on the phase to which the winding to be analysed belongs.

Fault 5 corresponds to a fault between the terminals of the winding to be analysed, in other words a short circuit of the entire winding.

Fault 6 corresponds to a fault between the terminals of a winding belonging to the same phase as the winding to be analysed.

Fault 7 corresponds to a short circuit present on a turn of the windings belonging to the same phase as the winding to be analysed. This fault causes overheating of the transformer.

Fault 8 corresponds to a short circuit present on several turns belonging to the same phase as the winding to be analysed. This fault causes overheating of the transformer.

Fault 9 corresponds to a short circuit fault such as a short circuit between turns, between terminals or on an additional turn. It indicates that the fault is located on a phase adjacent to the phase on which the measurement was made, and that the phase on which the fault is located is the only adjacent phase, in other words it is immediately adjacent to the phase on which the measurement was made. Thus, if the fault is located on the central core, an analysis of the other phases will produce this code because the central phase is the only phase immediately adjacent to the left and right phases.

Fault 10 also corresponds to a short circuit fault such as a short circuit between turns, between-terminals or on an additional turn. However, it indicates that the fault is not on a single phase located immediately adjacent to the phase on which the measurement was made. Thus, if the fault is located on the left core, the analysis of the central phase will produce this code because there are actually two phases and not only one immediately adjacent to the central phase.

Fault 11 corresponds to an axial displacement of the winding to be analysed, but without it being affected by excessive local damage.

Fault 12 corresponds to buckling of an inner winding.

Fault 13 corresponds to local mechanical damage on the winding to be analysed.

Fault 14 corresponds to poor electrical continuity in the winding to be analysed. This poor continuity may be related to a bad measurement contact.

As described above, each fault type i is associated with a certainty factor Ci in the expert system.

Each certainty factor Ci is a variable that may be equal to a real value between 1 (fault certainty) and −1 (fault impossible). Each certainty factor is initialised to 0.

Let Ci′ be the certainty factor associated with fault i before application of a rule; let Ci″ be the certainty factor associated with the same fault i determined by the said rule; let Ci be the current certainty factor to be calculated. For example, this certainty factor Ci will be determined using the following principles:
If Ci′>0 and Ci″>0 then:
   Ci=Ci′+Ci″(1−Ci′)
If Ci′=0
   Ci=Ci″
if Ci′>0 and Ci″<0 or if Ci′<0 and Ci″>0
then:

$$Ci = \frac{{Ci}^{′} + {Ci}^{″}}{1 - min ( \vert {Ci}^{′} \vert , \vert {Ci}^{″} \vert )}$$
If Ci′<0 and Ci″<0 then:
   Ci=Ci′+Ci″(1+Ci′)

Consider the example in which Ci′=0.5 and Ci″=0.5; the resulting certainty factor Ci is equal to 0.75.

Therefore this certainty factor Ci equal to 0.75 becomes the new certainty factor Ci′. If it is combined again with a certainty factor Ci″ equal to 0.5, the certainty factor becomes 0.875.

However, if the certainty factor equal to 0.75 is combined with a certainty factor Ci″ equal to −0.5 instead of 0.5, the certainty factor becomes 0.5 and not 0.875.

Note that the combination of any certainty factor other than −1 with 1 will give a new certainty factor equal to 1.

Note also that the combination of any certainty factor not equal to 1, with −1 will give a certainty factor equal to −1.

Finally, note that the combination of 1 with −1 will give an indefinite value.

The rules applied by the expert system fix a value of Ci″ depending on whether or not specific conditions on parameters are satisfied. For example, the rules applied by the expert system are as follows:
/*rule 1*/
if (ρ₁<0.25)
then (C4″){0.5} (in other words the value of 0.5 and the existing value of C4′ are combined using the principles described above).
(C8″){0.5}
(C7″){−0.5}
(C5″){0.25}
(C6″){0.25}
/*rule 2*/
if (ρ₂<normal)
then (C8″){0.25}
(C7″){−0.25}
(C5″){0.25}
(C6″){0.25}
/*rule 3*/
if ((ρ₂<normal) and (ρ₂>0.5))
then (C4″){0.5}
/*rule 4*/
if ((ρ₂<normal) and (ρ₂>0.7))
then (C9″){0.1}
(C10″){0.1}
(C11″){0.25}
(C12″){0.25}
/*rule 5*/
if (ρ₃<normal)
then (C5″){0.5}
/*rule 6*/
if ((ρ₃<normal) and (ρ₃>0.7))
then (C11″){0.5}
(C12″){0.5}
/*rule 7*/
if ((ρ₃<normal) and (ρ₃>0.9))
then (C8″){0.1}
/*rule 8*/
if (ρ₄<normal)
then (C5″){0.25}
(C6″){−0.7}
/*rule 9*/
if ((ρ₄<normal) and (ρ₄>0.7))
then (C1″){0.5}
(C11″){0.25}
(C12″){0.25}
(C13″){0.5}
/*rule 10*/
if ((ρ₄<normal) and (ρ₄>0.9))
then (C3″){0.1}
(C8″){0.1}
/*rule 11*/
if (presence of blip frequency)
then (C4″){0.5}
(C8″){−0.5}
(C5″){−0.7}
(C6″){−0.7}
/*rule 12*/
if (absence of blip frequency)
then (C4″){−0.25}
/*rule 13*/
if (VR_{f1}<0.75)
then (C5″){0.5}
(C6″){0.5}
/*rule 14*/
if ((VR_{f1}<0.9) and (VR_{f1}>0.75))
then (C2″){0.25}
(C3″){0.5}
/*rule 15a*/
if (VR_{f1}<0.9)
then (C4″){−1}
(C7″){−1}
(C10″){−1}
/*rule 15b*/
if (VR_{f1}<1.1)
then (C4″){−0.5}
(C8″){−1}
(C9″){−1}
/*rule 16*/
if ((VR_{f1}<1.25) and (VR_{f1}>1.1)
then (C7″){0.5}
(C10″){0.5}
/*rule 17*/
if ((VR_{f1}<1.5) and (VR_{f1}>1.25))
then (C9″){0.5}
/*rule 18*/
if (VR_{f1}>1.5)
then (C8″){0.5}
/*rule 19*/
if ((VR_{f1}<5) and (VR_{f1}>1.5))
then (C4″){0.5}
/*rule 20*/
if (VR_{f1}>5)
then (C4″){−0.25}
/*rule 21*/
if (absence of a second resonant frequency)
then (C4″){0.25}
(C8″){0.25}
(C7″){0.25}
(C9″){0.25}
(C10″){0.25}
/rule 22*/
if (presence of a second resonant frequency)
then (C4″){−1}
(C8″){−1}}
(C7″){−1}
(C9″){−1}
(C10″){−1}
/*rule 23*/
if ((VR_{f2}<0.9) and (VR_{f2}>0.75))
then (C2″){0.25}
(C3″){0.5}
/*rule 24*/
if (VR_{f3}<0.95)
then (C11″){−0.5}
(C12″){0.5}
/*rule 25*/
if (VR_{f3}>1.05)
then (C11″){0.5}
(C12″){−0.5}
/*rule 26*/
if ((VR_{f3}<1.05) and (VR_{f3}>0.95))
then (C11″){−0.5}
(C12″){−0.5}
/*rule 27*/
if ((VR_{f4}<0.9) or (VR_{f4}>1.1))
then (C1″){0.25}
(C13″){0.25}
/*rule 28*/
of (VR_{f4}<0.9)
then (C11″){−0.25}
(C12″){0.25}
/*rule 29*/
if (VR_{f4}>1.1)
then (C11″){0.25}
(C12″){−0.25}
/*rule 30*/
if (VRₙ<1)
then (C13″){−0.5}
/*rule 31*/
if ((VRₙ<1.2) and (VRₙ>1.1))
then (C13″){0.25}
/*rule 32*/
if (VRₙ>1.2)
then (C13″){0.5}
/*rule 33a*/
if (VRₖ₁>normal)
then (C2″){−0.25}
(C4″){−1}
(C8″){−1}
(C7″){−0.5}
(C5″){−1}
(C6″){−1}
/*rule 33b*/
of (VRₖ₁=normal)
then (C4″){−0.5}
(C8″){−5}
(C5″){−1}
(C6″){−1}
/*rule 34*/
if ((VRₖ₁<normal) and (VRₖ₁>0.8))
then (C2″){0.25}
/*rule 35*/
if ((VRₖ₁<normal) and (VRₖ₁>0.35))
then (C7″){0.5}
/*rule 36*/
if (((VRₖ₁<normal) or (VRₖ₁<0.85)) and (VRₖ₁>0.15))
then (C4″){0.5}
(C8″){0.5}
/*rule 37*/
if (VRk1<0.15)
then (C5″){0.5}
(C6″){0.5}
/*rule 38*/
if (VRₖ₂<−3)
then (C14″){1}

The term “normal” above means possible variations in normal usage circumstances. The user can adjust “normal” type variation ranges.

For example, the normal variations given in table 2 below could be used for a single winding.

TABLE 2

| Parameter | Normal variation |
|---|---|
| ρ2 | 0.995 |
| ρ3 | 0.995 |
| ρ4 | 0.955 |
| VRₖ₁ (see below) | +/−3 dBm |

The normal variation of the relative variation of the minimum gain at low frequency has to be estimated, as a function of its value in the reference measurement and the normal variation as an absolute value. If the minimum gain in the reference measurement is −100 dBm, the normal variation range is 0.94 to 1.06. If the minimum gain in the base measurement is −30 dBm, the normal variation range is 0.80 to 1.20.

The expert system comprises
thirteen inputs, corresponding to the eleven parameters and to the two presence indicators,
fourteen intermediate outputs, each corresponding to one fault type,
a final output diagnosing the fault type(s).

After all the rules have been applied, each of the 14 intermediate outputs (corresponding to a fault type) in the expert system will be associated with a certainty factor Ci (where i varies from 1 to 14).

The final diagnostic is made by applying the following principles:
if there is no certainty factor more than 0 on any intermediate output, the diagnostic corresponds to a lack of fault,
if the certainty factor on one or several intermediate outputs is more than 0 and if the certainty factor on one intermediate output is more than the others, the diagnostic corresponds to the presence of a fault associated with this last intermediate output,
if the certainty factor on two (or more) outputs is more than 0 and if the certainty factors on two outputs are more than the others, the diagnostic corresponds to the presence of the two faults associated with the previously mentioned outputs, unless one of the following exceptions occurs:
if the two faults are type 4 and type 8, the diagnostic corresponds to the presence of a type 4 or a type 8 fault respectively,
if the two faults are type 5 and type 6, the diagnostic corresponds to the presence of a type 6 fault,
if the two faults are type 11 and type 12, the diagnostic corresponds to the presence of a type 11 or type 12 fault respectively,
if the two faults are type 1 and type 13, the diagnostic corresponds to a type 1 fault,
if the two faults are type 8 and type 9 (or type 10), the diagnostic corresponds to the presence of a type 8 fault,
if three (or more) outputs have a certainty factor of more than 0 and if three (or more) outputs have the same certainty factor more than the others, the diagnostic corresponds to an unidentified fault.

Obviously, the invention is not limited to the embodiment that has just been described.

In particular, the expert system can be based on rules other than those described above that are only given as an example.

1. Method of diagnosing at least one fault on a transformer winding comprising the following steps:
measure the impedance of the said winding as a function of the frequency, the said measurement being represented in the form of a first voltage gain (k),
compare the said impedance measurement with a reference measurement represented in the form of a second voltage gain (k′),
the said method being characterised in that it comprises a step to determine the relative variation of the first resonant frequency exceeding 10 kHz, the said relative variation being obtained by comparing the said first and second gains (k, k′).

2. Method according to claim 1, characterised in that it includes a step to determine the relative variation of the last resonant frequency less than 1 MHz.

3. Method according to either claim 1 or 2, characterised in that it includes a step to determine the presence of a resonant frequency less than the fundamental resonant frequency.

4. Method according to claim 1, characterised in that it includes a step to determine the absolute variation of the maximum gain within a predetermined interval.

5. Method according to claim 4, characterised in that the said predetermined interval is [1 kHz-100 kHz].

6. Method according to claim 1, characterised in that it includes a step to determine the relative variation of a second resonant frequency following the fundamental resonant frequency.

7. Method according to claim 1, characterised in that it includes the following steps:
determine four correlation coefficients (ρ₁, ρ₂, ρ₃, ρ₄) of the said first and second gains (k, k′) in the four frequency ranges [100 Hz, 1 kHz], [1 kHz-10 kHz], [10 kHz-100 kHz] and [100 kHz-1 MHz],
determine the relative variation of the minimum gain for a frequency less than 10 kHz,
determine the absolute variation of the maximum gain in a predetermined frequency interval,
determine the relative variation of the fundamental resonant frequency,
determine if a second resonant frequency is present following the fundamental resonant frequency,
determine the relative variation of the said second resonant frequency following the fundamental resonant frequency,
determine if a resonant frequency is present less than the fundamental resonant frequency,
determine the relative variation of the last resonant frequency less than 1 MHz,
determine the relative variation of the number of resonant frequencies within a predetermined interval.

8. Method according to claim 7, characterised in that the said relative variation of the number of resonant frequencies is made within the interval [100 kHz; 1 MHz].

9. Method according to claim 7, characterised in that the said determination of the absolute variation of the maximum gain is made within the interval [1 kHz; 100 kHz].

10. Method according to claim 1, characterised in that it includes the following steps:
inject the results of each of the said determinations of relative variation and/or presence into an expert computer system,
the said expert system determines and identifies fault(s).

11. Method according to claim 10, characterised in that it includes the following steps:
assignment of a certainty factor to each fault that might be determined,
determination and identification of the fault(s) based on several rules modifying the said certainty factors as a function of the said results of each of the said determinations of relative variation and/or presence.

12. Method according to claim 11, characterised in that the method of calculating each certainty factor is based on the following principles:
If CF′>0 and CF″>0 then
CF=CF′+CF″(1−CF′)
If CF′=0
CF=CF″
If CF′>0 and CF″<0 or if CF′<0 and CF″>0
then:
$$CF = \frac{{CF}^{′} + {CF}^{″}}{1 - min ( \vert {CF}^{′} \vert , \vert {CF}^{″} \vert )}$$
If CF′<0 and CF″<0 then
CF=CF′+CF″(1+CF′)
where CF denotes the current value of the certainty factor, CF′ denotes the value before application of one of the said rules, and CF″ denotes the value of the certainty factor determined from one of the said rules and applied to CF′.

13. Expert computer system for implementation of the method according to claim 11, characterised in that it comprises:
a plurality of inputs adapted to receive the results of each of the said determinations of relative variation and/or presence indicators,
a plurality of outputs called intermediate outputs, corresponding to the number of detectable faults, each output being adapted to output a certainty factor calculated from the said plurality of rules,
a so-called final output adapted to produce a diagnostic of the fault(s) present on the said transformer winding.
